(19) United States
(12) Patent Application Publication
(10) Pub. No.: US 2023/0228554 A1
(43) Pub. Date: Jul. 20, 2023

(54) EXCITATION AND SENSING OF A NETWORK OF LC OSCILLATORS

(71) Applicants: STMicroelectronics (Grenoble 2) SAS, Grenoble (FR); STMicroelectronics S.r.l., Agrate Brianza (MB) (IT); STMicroelectronics (Alps) SAS, Grenoble (FR)

(72) Inventors: Santi Carlo Adamo, Aci Castello (IT); Cyril Joubert, Grenoble (FR); Bastien Mahtal, Grenoble (FR); Damien Giot, Grenoble (FR); Hugo Gicquel, Grenoble (FR); Alexandre Gimard, Chirens (FR)

(21) Appl. No.: 18/147,927

(22) Filed: Dec. 29, 2022

(30) Foreign Application Priority Data
Jan. 17, 2022 (FR) 2200373

(51) Int. Cl. G01B 7/30; H03B 5/08

(52) U.S. Cl. CPC G01B 7/30; H03B 5/08

(57) ABSTRACT

An electronic system includes a first LC oscillator connected to a first general-purpose input/output (GPIO) circuit and a second LC oscillator connected to a second GPIO circuit. A threshold generator is coupled to an input of the comparator. A control circuit is configured to control a measurement phase comprising a first capture phase and a second capture phase. A microcontroller is coupled to the control circuit and a power management circuit is configured to switch-off the microcontroller following activation of the control circuit by the microcontroller. The control circuit is configured to control the application of an excitation signal to the each oscillator via the respective GPIO circuit, control the GPIO circuit so that oscillations of the oscillator are provided to the comparator, and count, based on an output of the comparator, a number of oscillations in the oscillator exceeding a threshold output by the threshold generator.

### CROSS-REFERENCE TO RELATED APPLICATIONS

This application claims the priority benefit of French patent application number 22/00373, filed on Jan. 17, 2022, which is hereby incorporated by reference.

### TECHNICAL FIELD

The present disclosure relates to the excitation and sensing of a network of LC oscillators.

### BACKGROUND

Electronics systems for counting a number of revolutions of a rotating wheel are known. For example, when the rotating wheel is disposed inside a pipe in which a fluid is flowing, the rotating wheel is driven by the fluid movement inside the pipe. Thus, counting the number of revolutions of the wheel allows for determining the quantity of fluid which flows in the pipe.

FIG. 1 illustrates an example of a method for determining a position, or state, of a rotating wheel 1 at a given moment. Indeed, by determining the position of the wheel at a plurality of successive instants, it is possible to determine the number of revolutions the wheel has done between two of this plurality of successive instants.

The wheel 1 is configured to rotate around an axis (not represented in FIG. 1). This axis is, in the FIG. 1, perpendicular to the plane of the FIG. 1, and passes through the center O of the wheel 1. The wheel 1 will be disposed inside a pipe wherein a fluid is flowing, so that the movement of the fluid drives the rotation of the wheel 1.

A first half 2 of the wheel 1 is covered with a metal 4, whereas the other half 3 of the wheel 1 is not.

At least two LC oscillators LCA and LCB are provided. These oscillators LCA, LCB, for example, belong to an electronic system for determining a position of the rotating wheel 1 around its rotation axis.

The oscillators LCA and LCB are disposed proximate to the wheel 1, so that when oscillator LCA or LCB is facing a part of the wheel 1 which is covered with metal 4, a damping time of free oscillations in the oscillator is faster than when the oscillator is facing a part of the wheel 1 which is not covered with metal 4.

The positions of the oscillators LCA and LCB with respect to the rotation axis of the wheel 1 are fixed. In other words, the oscillators LCA and LCB do not move with respect to this axis, whereas the wheel 1 could rotate around this axis.

Oscillators LCA and LCB are disposed near different regions of the wheel 1. Oscillator LCA is, for example, disposed near a first region of the wheel 1 which, for example, corresponds to a quarter of the wheel, the oscillator LCB being disposed near a second region of the wheel 1 which, for example, corresponds to another quarter of the wheel 1.

For example, in FIG. 1, four regions of the wheel 1 corresponding to four quarters of the wheel 1 are delimited by dotted lines, these four regions being fixed with respect to the rotation axis of the wheel 1. The oscillator LCB is disposed near the region, or quarter, of the wheel 1 which is on the left and bottom side of FIG. 1, and the oscillator LCA is disposed near the region, or quarter, of the wheel 1 which is on the right and bottom side of FIG. 1.

Thus, measuring the damping time of the oscillators LCA and LCB, or, in other words, sensing the oscillators LCA and LCB, allows for determining the position of the wheel 1 around its axis. By determining the position of the wheel 1 at two different instants, it is possible to determine by which amount the wheel 1 has rotated around its axis between these two instants. Thus, it is possible determining the flow of the fluid inside the pipe.

For example, the damping time of an oscillator is determined by counting, during a given period, a number of free oscillations which are above a threshold. Indeed, the lower the counted number is, the faster the damping time.

In known systems for determining a position of a rotating wheel around its rotation axis using LC oscillators as described in relation with FIG. 1, each time an LC oscillator is excited to induce free oscillations in the LC oscillator, this excitation is done under the control of a microcontroller of the system, the microcontroller being active during the excitation of the LC oscillator. Further, in such known systems, the sensing of an oscillator which has been first excited is also done under the control of the microcontroller of the system, the microcontroller being then active during the sensing of the oscillator.

However, the more the microcontroller is active, the more the consumption of the system.

### SUMMARY

Embodiments relate generally to electronic devices. Particular embodiments relate to the excitation and sensing of a network of LC oscillators, for example for use in electronic devices for fluid metering.

Embodiments can overcome all or some of the drawbacks of known systems of the type described above. For example, there is a need to reduce the consumption of such known systems. One embodiment addresses all or some of the drawbacks of known systems of the type described above.

For example, one embodiment allows reducing the consumption of a system for determining a position of a rotating wheel compared to known systems of the type described above.

One embodiment provides an electronic system comprising a first LC oscillator connected to a first general-purpose input/output circuit. A second LC oscillator is connected to a second general-purpose input/output circuit. A threshold generator is configured to provide a first threshold voltage to a comparator. A control circuit is configured, when the control circuit is activated, to control a measurement phase comprising at least a first capture phase and a second capture phase. A microcontroller is configured to activate the control circuit. A power management circuit is configured to switch-off the microcontroller following the activation of the control circuit by the microcontroller. The control circuit is configured, when implementing the first phase of capture, to control an application of an excitation signal to the first oscillator via the first circuit, control the first circuit so that oscillations of the first oscillator are provided to the comparator, and count, based on the comparator output, a first number of oscillations in the first oscillator exceeding the first threshold. The control circuit is configured, when implementing the second phase of capture, to control an application of an excitation signal to the second oscillator via the second circuit, control the second circuit so that oscillations of the second oscillator are provided to the comparator, and count, based on the comparator output, a second number of oscillations in the second oscillator exceeding the first threshold.

According to one embodiment, for providing oscillations of the first oscillator to the comparator, the control circuit is configured to control, via a third terminal of the first circuit, a coupling of first and second terminals of the first circuit, the first terminal being connected to the first oscillator and the second terminal being coupled to the comparator, and, for providing oscillations of the second oscillator to the comparator, the control circuit is configured to control, via a third terminal of the second circuit, a coupling of first and second terminals of the second circuit, the first terminal being connected to the second oscillator and the second terminal being coupled to the comparator.

According to one embodiment, the control circuit is configured to control the application of a pulse signal on a fourth terminal of the first circuit for controlling the application of the excitation signal to the first oscillator, and to control the application of the pulse signal on a fourth terminal of the second circuit for controlling the application of the excitation signal to second oscillator.

According to one embodiment, the system comprises a pulse generator circuit for generating the pulse signal, the control circuit being configured, when activated, to control the pulse generator circuit.

According to one embodiment, the first oscillator is connected between the first circuit and a first electrode of a capacitor having a second electrode connected to a node for receiving a reference potential and the second oscillator is connected between the second circuit and the first electrode of the capacitor. The electronic system comprises a supplementary general-purpose input/output circuit connected to the first electrode of capacitor. The threshold generator is configured to provide a bias potential to the first electrode of the capacitor via the supplementary general-purpose input/output circuit.

According to one embodiment, the microcontroller is configured, before activating the control circuit, to configure the supplementary general-purpose input/output circuit for coupling with each other first and second terminals of supplementary circuit, the first terminal being connected to the first electrode of the capacitor and the second terminal being configured to receive the bias potential.

According to one embodiment, at an end of the last capture phase of each measurement phase, the control circuit is configured to determine whether a temporization duration has to elapse before controlling a beginning of the next measurement phase.

According to one embodiment, when the temporization duration is not null, the control circuit is configured to disable the threshold generator during temporization duration.

According to one embodiment, when the temporization duration is not null, the control circuit is configured to disable the comparator during temporization duration.

According to one embodiment, the system comprises an integrated circuit chip comprising the comparator, the threshold generator, the control circuit, the microcontroller and the power management circuit, the first and second oscillators being disposed off-chip.

According to one embodiment, the system comprises a first voltage domain comprising the control circuit and a second voltage domain comprising the microcontroller, the power management circuit being configured to switch-off the second voltage domain following the activation of the control circuit by the microcontroller.

According to one embodiment, at each measurement phase, the control circuit is configured to compare the first number and the second number with a second threshold to determine a position of a rotating wheel, preferably the control circuit being configured to send a wake-up event to the power management circuit when a number of revolution of the wheel reaches a target value, the number of revolution being determined by the control circuit based on the position of the rotating wheel determined at each of a plurality of measurement phases, and the power management circuit being configured to switch-on the microcontroller when receiving the wake-up event.

According to one embodiment, at each measurement phase, the control circuit is configured to compare the first number and the second number with a low boundary value and a high boundary value, preferably the control circuit being configured to send a wake-up event to the power management circuit when at least one of the first and second number is outside a range of values from the low boundary value to the high boundary value, and the power management circuit being configured to switch-on the microcontroller when receiving the wake-up event.

According to one embodiment, the electronic system further comprises a third LC oscillator connected to a sixth general-purpose input/output circuit, at least one measurement phase controlled by the control circuit comprises a third capture phase further to the first and the second capture phases, and the control circuit is configured, when implementing the third phase of capture, to control an application of an excitation signal to the third oscillator via the sixth circuit, control the sixth circuit so that oscillations of the third oscillator are provided to the comparator, count, based on the comparator output, a third number of oscillations in the third oscillator exceeding the first threshold, and detect a tamper by comparing the third number with a third threshold and, preferably, to send a wake-up event to the power management circuit and an interruption signal to the microcontroller when a tamper is detected.

One embodiment provides a method implemented in an electronic system, the method comprising activating a control circuit with a microcontroller, switching-off, with a power management circuit, the microcontroller following the activation of the control circuit by the microcontroller, and implementing, with the activated control circuit, a measurement phase comprising at least a first capture phase with a first LC oscillator connected to a first general-purpose input/output circuit and a second capture phase with a second LC oscillator connected to a second general-purpose input/output circuit. The first capture phase comprises controlling, with the control circuit, an application of an excitation signal to the first oscillator via the first circuit, controlling the first circuit with the control circuit so that oscillations of the first oscillator are provided to a comparator receiving a first threshold voltage from a threshold generator, counting, based on the comparator output, a first number of oscillations in the first oscillator exceeding the first threshold. The second capture phase comprises controlling, with the control circuit, an application of an excitation signal to the second oscillator via the second circuit, controlling the second circuit with the control circuit so that oscillations of the second oscillator are provided to the comparator receiving the threshold voltage, and counting, based on the comparator output, a second number of oscillations in the second oscillator exceeding the first threshold.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1, described above, illustrates an example of a method for determining a position of a rotating wheel;

FIG. 2 illustrates an example of an electronic system according to one embodiment;

FIG. 3 illustrates an example of a method according to one embodiment, the method being implemented in an electronic system of the type described in relation with FIG. 2;

FIG. 4 illustrates an example of an electronic system according to one other embodiment;

FIG. 5 illustrates an example of a method according to one other embodiment, the method being implemented in an electronic system of the type described in relation with FIG. 4;

FIG. 6 illustrates an example of two steps of the methods of FIGS. 3 and 5 according to one embodiment;

FIG. 7 illustrates an example of another step of the methods of FIGS. 3 and 5 according to one embodiment;

FIG. 8 illustrates an example of another step of the methods of FIGS. 3 and 5 according to one embodiment;

FIG. 9 illustrates an example of a method according to one embodiment; and

FIG. 10 is a chronogram illustrating the method of FIGS. 5 and 9 according to one embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, general-purpose input/output circuits (GPIO circuits) are well known from those skilled in the art and will not be described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around,” “approximately,” “substantially,” and “in the order of” signify within 10%, and preferably within 5%.

It is here proposed an electronic system in which a microcontroller activates a control circuit. The activated control circuit then controls a measurement phase comprising at least a capture phase with a first LC oscillator and a capture phase with a second LC oscillator. Each capture phase comprises an excitation phase of the corresponding oscillator, the excitation phase being also controlled by the control circuit. Further, once the control circuit is activated, at least one measurement phase is controlled by the control circuit without any intervention from the microcontroller, which is powered off during all the duration of the at least one measurement phase. This allows to reduce the power consumption of the microcontroller, and thus of the system.

According to one embodiment, once the microcontroller has activated the control circuit, a circuit is configured to switch off the microcontroller, for example to switch off the supply voltage of a voltage domain comprising the microcontroller. When the microcontroller is off, the system is said to be, for example, in low power mode.

For example, in low power mode, the microcontroller and the components of the system which are in the same voltage domain than the microcontroller are powered down, or, in other words, switched off. In low power mode, the control circuit and the components controlled by the control circuit are in at least one another voltage domain, which still receives a power supply voltage, for example from the circuit for controlling the power supply. For example, the microcontroller belongs to a first supply voltage domain, the control circuit belongs to a second supply voltage domain, and at least some of components controlled by the control circuit belong to a third supply voltage domain. For example, the first and second supply voltage domains are configured for supplying digital circuits, and the third voltage domain is configured for supplying analog circuits. For example, the third voltage domain is supplied by the voltage level provided by a battery supplying the system, for example a voltage level equal to 3.3 V.

According to one embodiment, in low power mode, the control circuit CTRL, and for example the voltage domain the control circuit belongs to, receive a power supply which is lower than the one received when the system is in a nominal power supply mode. This allows to further reduce the power consumption.

According to one embodiment, in low power mode, the control circuit CTRL, and for example the voltage domain the control circuit belongs to, receive a clock signal which has a frequency lower than the one received when the system is in a nominal power supply mode. This allows to further reduce the power consumption.

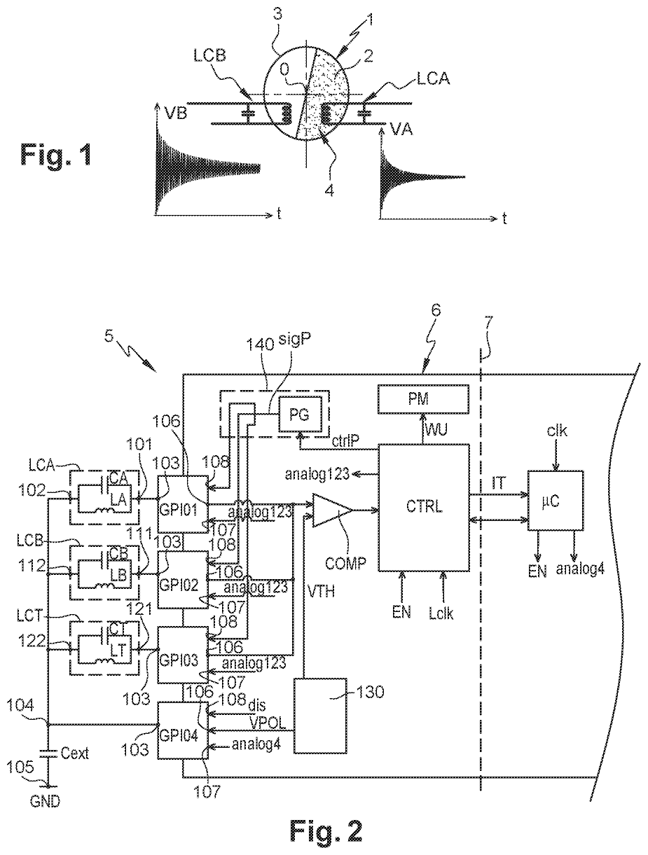

FIG. 2 illustrates, under the form of blocks, an example of such an electronic system 5 according to one embodiment.

The electronic system 5 comprises an LC oscillator LCA (delimited in dotted lines in FIG. 2). For example, the oscillator LCA comprises a capacitor CA and an inductor LA connected in parallel between two nodes 101 and 102.

The LC oscillator LCA is connected to a general-purpose input/output circuit GPIO1. For example, the node 101 of the oscillator LCA is connected to the circuit GPIO1. For example, the oscillator LCA, and, more particularly its node 101, is connected to a terminal 103 of the circuit GPIO1.

More specifically, the oscillator LCA couples the circuit GPIO1 to a node 105 configured for receiving a reference potential, for example the ground GND. For example, the oscillator LCA is connected between the circuit GPIO1 and an electrode 104 of a capacitor Cext, the other electrode of the capacitor Cext being connected to the node 105. For example, node 102 of the oscillator LCA is connected to the electrode 104 of capacitor Cext.

The electronic system 5 comprises an LC oscillator LCB (delimited in dotted lines in FIG. 2). For example, the oscillator LCB comprises a capacitor CB and an inductor LB connected in parallel between two nodes 111 and 112. Preferably, capacitor CA is identical to capacitor CB and inductor LA is identical to inductor LB.

The LC oscillator LCB is connected to a general-purpose input/output circuit GPIO2. For example, node 111 of the oscillator LCB is connected to the circuit GPIO2.

The circuit GPIO2 is, preferably, identical to circuit GPIO1. For example, the oscillator LCB, and, more particularly its node 111, is connected to the terminal 103 of the circuit GPIO2.

More specifically, the oscillator LCB couples the circuit GPIO2 to the node 105. For example, the oscillator LCB is connected between the circuit GPIO2 and the electrode 104 of capacitor Cext. For example, node 112 of the oscillator LCB is connected to the electrode 104 of capacitor Cext.

As already described in relation with FIG. 1, the oscillators LCA and LCB are used to determine the position of the rotating wheel 1, which is not represented in FIG. 2. In alternative embodiments (not shown), the system 5 may comprise more than two LC oscillators used to determine the position of the wheel 1. Indeed, increasing the number of LC oscillators used for determining the position of the wheel 1 allows increasing the precision the position of the wheel 1 is determined with.

In the embodiment of FIG. 2, further to determining the position of the wheel 1, the system 5 is configured to detect that a metallic surface has been placed near the wheel 1, for example by a fraudster, in order to make the system 5 believes that the wheel 1 is not rotating at all.

In such an embodiment, the system 5 comprises an LC oscillator LCT (delimited in dotted lines in FIG. 2). For example, the oscillator LCT comprises a capacitor CT and an inductor LT connected in parallel between two nodes 121 and 122.

The LC oscillator LCT is connected to a general-purpose input/output circuit GPIO3. For example, node 121 of the oscillator LCT is connected to the circuit GPIO3.

The circuit GPIO3 is, preferably, identical to circuits GPIO1 and GPIO2. For example, the oscillator LCT, and, more particularly its node 121, is connected to the terminal 103 of the circuit GPIO3.

More specifically, the oscillator LCT couples the circuit GPIO3 to the node 105. For example, the oscillator LCT is connected between the circuit GPIO3 and the electrode 104 of capacitor Cext. For example, node 122 of the oscillator LCT is connected to the electrode 104 of capacitor Cext.

In operation, the oscillator LCT is placed near or next to the wheel 1, but is not placed facing a quarter of the wheel 1 such as the oscillators LCA and LCB. Thus, the damping time of the oscillator LCT should always correspond to a case where the oscillator LC is not facing a metallic surface. However, if the damping time of the oscillator LCT decreases, this means that the oscillator LCT is facing a metallic surface, for example a metallic surface which has been placed near to the wheel 1, for example by a fraudster. Thus, measuring the damping time of the oscillator LCT allows for detecting a tamper, which may, for example, leads the system 5 to alert a user of a fraudulent usage.

According to an alternative embodiment, the system 5 does not comprise the oscillator LCT and is not configured to detect a tamper.

The system 5 comprises a comparator COMP, or, in other words, a circuit COMP configured to compare two signals, for example two voltages, with each other. The comparator COMP is configured to output a signal in a first binary state if a first input of the comparator COMP has a level lower than a second input of the comparator COMP, and in a second binary state otherwise.

The system 5 comprises a circuit 130 configured to provide a threshold VTH to the comparator COMP. The threshold VTH, for example a voltage threshold, is provided by the circuit 130 to one of the first and second inputs of the comparator COMP. For example, the circuit 130 comprises a digital-to-analog converter (not shown in FIG. 2) configured to provide the voltage VTH.

The system 5 comprises a control circuit CTRL. When the circuit CTRL is activated, the circuit CTRL is configured to implement, or control, at least one measurement phase MEAS, for example a plurality of successive measurement phases MEAS. Each measurement phase MEAS allows, for example, to determine the position of the wheel 1 relative to its rotation axis.

Each measurement phase MEAS comprises at least a capture phase CAP using the oscillator LCA, and a capture phase CAP using the oscillator LCB.

Each capture phase CAP comprises an excitation phase of the corresponding LC oscillator. Each capture phase CAP comprises counting a number of free oscillations in the corresponding LC oscillator which exceed the threshold VTH, or, in other words, a phase of sensing the LC oscillator.

In the embodiment illustrated in FIG. 2, the system 5 comprises the oscillator LCT. Thus, in this case, each measurement phase MEAS may further comprises a capture phase CAP using the oscillator LCT.

According to one embodiment, the general-purpose input/output circuits of the system 5 each corresponds to an input/output of an integrated circuit chip 6. The LC oscillators and the capacitor Cext of the system 5 are then external to the chip 6.

The activation of the circuit CTRL is done by a microcontroller C of the system 5. For example, the activation of the circuit CTRL by the microcontroller μC is by a bit EN provided by the microcontroller μC to the circuit CTRL.

For example, the microcontroller μC activate the circuit CTRL by writing the bit EN at a first binary state in a register (not shown), for example a register of the circuit CTRL. The circuit CTRL is, for example, deactivated when the bit EN at a second binary state is written in the register.

The system 5 further comprises a circuit PM. The circuit PM is configured to switch off the microcontroller μC, or, in other words, to switch the system 5 in low power mode, once the circuit CTRL has been activated by the microcontroller PC. In other words, the circuit PM is configured to switch off the microcontroller μC after each activation of the circuit CTRL by the microcontroller μC.

According to one embodiment the chip 6 comprises at least two voltage domains, or, in other words, two power supply domains. These two voltage domains are schematically delimited by dotted lines 7 in FIG. 2. The microcontroller μC belongs to a first one of the two voltage domains. The circuit CTRL belongs to the second one of the two voltage domains. For example, all the components of the chip 6 controlled by the circuit CTRL when it is activated, also belong to the second one of the two voltage domains. In an alternative example, the components of the chip 6 controlled by circuit CTRL when it is activated belong to a third voltage domain, for example configured for supplying analog circuits from a battery supplying the system 5.

The circuit PM is, for example, configured to manage the power supply in the chip 6, or, in other words, to control the power supply provided to each voltage domains of the chip 6. For example, when the system 5 is in low power mode, the circuit PM is configured to shut down the power supply of the voltage domain comprising the microcontroller PC, or, in other words, to powered-off the microcontroller μC. For example, when the system 5 is in low power mode, the circuit PM is configured to maintain a power supply of the voltage domain comprising the circuit CTRL. Preferably, when the system 5 is in low power mode, the circuit PM is configured to provide a lower power supply voltage to the voltage domain of the circuit CTRL than the one provided when the system 5 is not in low power mode but, for example, in a nominal power supply mode.

According to one embodiment, the system 5 further comprises a general-purpose input/output circuit GPIO4 connected to the external capacitor Cext. Preferably, the circuit GPIO4 is identical to the circuit GPIO1. For example, the output 103 of the circuit GPIO4 is connected to the electrode 104 of the capacitor Cext. Further, the circuit 130 is configured to provide a bias potential VPOL to the electrode 104 of the capacitor Cext, via the circuit GPIO4. For example, the circuit 130 comprises a digital-to-analog converter (not shown on FIG. 2) configured to provide the bias potential VPOL. For example, circuit 130 comprises a buffer circuit between the output of this digital-to-analog converter and the output of circuit 130 on which the potential VPOL is provided.

For example, before activating the circuit CTRL and being switched in low power mode, the microcontroller μC configures the circuit GPIO4 so that the potential VPOL received by the circuit GPIO4, for example by terminal 106 of the circuit GPIO4, is transmitted to the electrode 104 of the capacitor Cext or, in other words, to the terminal 103 of the circuit GPIO4. For example, such configuration of the circuit GPIO4 is done by providing a given state of a digital signal analog4 on a terminal 107 of the circuit GPIO4. For example, the signal analog4 having this given state is written by the microcontroller μC in a register of the system 5, so that it is provided to the terminal 107 of the circuit GPIO4.

For example, before configuring the circuit GPIO4 so that potential Vpol is applied on node 104, the microcontroller μC may be configured to first discharge the capacitor Cext. For example, to discharge the capacitor Cext with the circuit GPIO4, the microcontroller μC first activates a terminal 108 of the circuit GPIO4 with a signal dis, so that the potential GND is applied by circuit GPIO4 on node 104. For example, the signal dis received on the terminal 108 of the circuit GPIO4 activates an output buffer circuit (“circuit tampon de sortie” in French) of the circuit GPIO4, the output buffer circuit having its input receiving a low binary state or level. In FIG. 2, the signal received by the input of the output buffer of the circuit GPIO4 is not represented. As an alternative example, the discharging of the capacitor Cext controlled by the microcontroller may be omitted.

In an alternative example, the configuration of the circuit GPIO4 for providing the potential VPOL to the capacitor Cext is done by the circuit CTRL once it has been activated.

As an example, the voltage Vpol is equal to half of the voltage difference between the reference potential GND and the maximum value of the potential that the system 5 may deliver to the LC oscillators when in low power mode. For example, this maximum value of potential is equal to the value of the supply voltage received by the circuit CTRL in low power mode. For example, this maximum value of potential is equal to the value of the supply voltage provided by a battery supplying the system 5.

During a measurement phase MEAS, and, more specifically, during a corresponding capture phase CAP done with the oscillator LCA, the circuit CTRL is configured to excite the oscillator LCA (excitation phase), so that free oscillations occur in the oscillator LCA, for example on node 101 of the oscillator LCA. In other words, the circuit CTRL is configured to control the application of an excitation signal to the oscillator LCA, for example to node 101 of the oscillator LCA, via the circuit GPIO1.

According to one embodiment, exciting the oscillator LCA is done by applying a pulse at the ground level (low pulse) to the node 101 of the oscillator LCA. In an alternative embodiment, exciting the oscillator LCA is done by applying a pulse at the supply voltage level (high pulse) to node 101 of the oscillator LCA, this supply voltage, for example, corresponding to the voltage provided by a battery supplying the system 5.

Applying an excitation pulse to the oscillator LC1 is, for example, done by providing a pulse sigP to a terminal 108 of the circuit GPIO1, which in turn applies a corresponding excitation pulse, for example at the ground level, on its terminal 103. The duration of the excitation pulse provided to the oscillator is equal to the duration TP of the pulse sigP.

For example, the pulse sigP received on the terminal 108 of the circuit GPIO1 activates an output buffer circuit (“circuit tampon de sortie” in French) of the circuit GPIO1, the output buffer circuit having its input receiving, for example, a low binary state or level, which, for example, corresponds to the ground potential. In FIG. 2, the signal received by the input of the output buffer of the circuit GPIO1 is not represented.

According to one embodiment where the pulse sigP is provided to the circuit GPIO1 for exciting the oscillator LCA, the system 5 comprises a circuit 140 (delimited in dotted lines in FIG. 2). The circuit CTRL is configured to control the circuit 140, or, in other words, to control when the circuit 140 provides the pulse sigP to the circuit GPIO1. For example, the generation of pulse sigP by circuit 140 is controlled by a signal ctrlP provided by circuit CTRL to circuit 140.

For example, the circuit 140 comprises a circuit PG for generating the pulse sigP. The generation of the pulse sigP by circuit PG is, for example, controlled by the signal ctrlP.

For example, the pulse sigP is provided to the terminals 108 of circuits GPIO1, GPIO2 and GPIO3 simultaneously. In an alternative example, the circuit 140 comprises a routing circuit controlled by the circuit CTRL, so that the pulse sigP is provided to only a selected one of the circuits GPIO1, GPIO2 and GPIO3.

According to one embodiment, for each capture phase CAP with the oscillator LCA, the excitation of the oscillator LCA is done, or begins, at an instant separated from the beginning of the capture phase CAP by a non-null duration iCAP. In an alternative embodiment, the duration iCAP is null, or, in other words, omitted.

During the capture phase CAP with the oscillator LCA, before excitation of the oscillator LCA ends or when the excitation of the oscillator LCA ends, the circuit CTRL is configured to control the circuit GPIO1 so that free oscillations occurring in the oscillator LCA from the end of the excitation of the oscillator LCA are provided to the comparator COMP. More specifically, the oscillations from the oscillator LCA are provided on one of the first and second inputs of the comparator COMP, the other one of the first and second inputs receiving the threshold VTH. Thus, the oscillations in oscillator LCA are compared with threshold VTH by comparator COMP. The part of the capture phase CAP during which free oscillations of the corresponding oscillator are provided to the comparator COMP corresponds to the sensing phase of the capture phase CAP.

In other words, during the capture phase CAP with the oscillator LCA, before or when excitation of the oscillator LCA ends, the circuit CTRL is configured to control the circuit GPIO1 so that voltage on node 101 is provided to the comparator COMP, via the circuit GPIO1. Said in further other words, during the capture phase CAP done with the oscillator LCA, before or when excitation of the oscillator LCA ends, the circuit CTRL is configured to select the oscillator LCA, via the circuit GPIO1.

The selection of the oscillator LCA is maintained by the circuit CTRL, for example, until the ends of the capture phase CAP. Preferably, the oscillator LCA is selected by the circuit CTRL at the beginning of the capture phase CAP, or, in other words, the selection of the oscillator LCA corresponds to the beginning of the capture phase CAP with the oscillator LCA.

For example, to select the oscillator LCA, the circuit CTRL is configured to control circuit GPIO1 so that the voltage on its terminal 103 is transmitted on its terminal 106, which is coupled, preferably connected to the comparator COMP. In other words, selecting the oscillator LCA means controlling the circuit GPIO1 so that its terminals 103 and 106 are coupled with each other. Such configuration of the circuit GPIO1 is done by providing a given state of a digital signal analog123 on the input 107 of the circuit GPIO1. The signal analog123 is, for example, a digital signal comprising a plurality of bits. Signal analog123 is provided to the inputs 107 of the circuits GPIO1 and GPIO2 and, in this embodiment where the system 5 comprises the oscillator LCT, to the input 107 of circuit GPIO3. The circuit CTRL is configured to provide the signal analog123.

During the capture phase CAP with the oscillator LCA, as long as the oscillator LCA is selected by circuit CTRL via the circuit GPIO1, each oscillation of the oscillator LCA which exceeds the threshold VTH is detected by the circuit CTRL, based on the switching of the output of the circuit COMP. For example, the circuit CTRL is configured to count a number of switching, or pulses, of the output of the comparator COMP, this number being representative of the number of oscillations which have exceeded the threshold VTH. In other words, the circuit CTRL is configured to count a number CNT of oscillations in the oscillator LCA which exceed the threshold VTH, based on the output of the comparator COMP. For example, the circuit CTRL comprises a circuit for counting number CNT based on the switching of the output of the comparator COMP. Counting number CNT, for example, corresponds to the sensing phase of the capture phase CAP.

At the end of the capture phase CAP done with the oscillator LCA, the circuit CTRL unselects the oscillator LCA, for example by changing the state of the signal analog123.

According to one embodiment, the circuit CTRL is configured to compare threshold THAB with the number CNT counted during the capture phase CAP with the oscillator LCA. When number CNT is above the threshold THAB, this means that the damping time is lower than when the counted number is below the threshold THAB. Thus, when the number CNT is above the threshold THAB, this means that the oscillator LCA is not facing the metal 4 of the wheel 1 (see FIG. 1), and when the number CNT is below the threshold THAB, this means that the oscillator LCA is facing the metal 4 of the wheel 1.

The circuit CTRL then controls the implementation of the capture phase CAP with the oscillator LCB. The capture phase CAP with the oscillator LCB is similar to the one with oscillator LCA except that circuit CTRL selects the oscillator LCB rather than oscillator LCA. Preferably, the oscillator LCB is selected for the whole duration of the capture phase CAP with the oscillator LCB.

In particular, during the capture phase CAP with the oscillator LCB, to select the oscillator LCB, the circuit CTRL is configured to control circuit GPIO2 so that the voltage on its terminal 103 is transmitted on its terminal 106, which is coupled, preferably connected to the comparator COMP. In other words, selecting the oscillator LCB means controlling the circuit GPIO2 so that its terminals 103 and 106 are coupled with each other. Such configuration of the circuit GPIO2 is done by providing, with circuit CTRL, a given state of a digital signal analog123 on the input 107 of the circuit GPIO2.

Further, the circuit CTRL is configured to excite oscillator LCB by controlling the application of an excitation signal to the oscillator LCB, via the circuit GPIO2, similarly to what has been done for exciting the oscillator LCA via the circuit GPIO1. This excitation phase of oscillator LCB is, for example, done by providing pulse sigP to the terminal 108 of the circuit GPIO2, which in turn applies a corresponding excitation signal on its terminal 103 for all the duration of the pulse sigP, similarly to what has been described for the excitation phase of oscillator LCA.

According to one embodiment, as for each capture phase CAP with the oscillator LCA, in each capture phase with oscillator LCB, the excitation of the oscillator LCB is done at an instant separated from the beginning of the capture phase CAP by the duration iCAP, which could be null.

During the capture phase CAP with the oscillator LCB, as long as the oscillator LCB is selected by circuit CTRL via the circuit GPIO2, each oscillation of the oscillator LCB which exceeds the threshold VTH is detected by the circuit CTRL, based on the switching of the output of the circuit COMP. For example, the circuit CTRL is configured to count the number CNT of switching, or pulses, of the output of the comparator COMP, this number being representative of the number CNT of oscillations of the oscillator LCB which have exceeded the threshold VTH. Counting number CNT, for example, corresponds to the sensing phase of the capture phase CAP.

At the end of the capture phase CAP done with the oscillator LCB, the circuit CTRL unselects the oscillator LCB, for example by changing the state of the signal analog123.

According to one embodiment, the circuit CTRL is configured to compare threshold THAB with the number CNT counted during the capture phase CAP with the oscillator LCB. When number CNT is above the threshold THAB, this means that the damping time is lower than when the counted number is below the threshold THAB. Thus, when the number CNT is above the threshold THAB, this means that the oscillator LCB is not facing the metal 4 of the wheel 1 (see FIG. 1), and when the number CNT is below the threshold THAB, this means that the oscillator LCB is facing the metal 4 of the wheel 1.

According to one embodiment, after determining for each of the oscillators LCA and LCB whether the oscillator is facing or not the metal 4 of the wheel 1, circuit CTRL is configured to deduce the position of the wheel 1 with respect to its rotation axis.

In the example embodiment illustrated by FIG. 2, the system 5 comprises the oscillator LCT. Thus, during a measurement phase MEAS, the circuit CTRL may control a capture phase CAP with the oscillator LCT in order to detect a tamper.

The capture phase CAP with the oscillator LCT is similar to the one with oscillator LCA or LCB except that circuit CTRL selects the oscillator LCT rather than oscillator LCA or LCB. Preferably, the oscillator LCT is selected for the whole duration of the capture phase CAP with the oscillator LCT.

In particular, during the capture phase CAP with the oscillator LCT, to select the oscillator LCT, the circuit CTRL is configured to control circuit GPIO3 so that the voltage on its terminal 103 is transmitted on its terminal 106, which is coupled, preferably connected to the comparator COMP. In other words, selecting the oscillator LCT means controlling the circuit GPIO3 so that its terminals 103 and 106 are coupled with each other. Such configuration of the circuit GPIO3 is done by providing, with circuit CTRL, a given state of a digital signal analog123 on the input 107 of the circuit GPIO3.

Further, the circuit CTRL is configured to excite oscillator LCT by controlling the application of an excitation signal to the oscillator LCT, via the circuit GPIO3, similarly to what has been done for exciting the oscillator LCA via the circuit GPIO1 or oscillator LCB via the circuit GPIO2. This excitation phase of oscillator LCT is, for example, done by providing pulse sigP to the terminal 108 of the circuit GPIO3, which in turn applies a corresponding excitation signal on its terminal 103 for all the duration of the pulse sigP, similarly to what has been described for the excitation phase of oscillator LCA.

According to one embodiment, as for each capture phase CAP with the oscillator LCA or LCB, in each capture phase CAP with oscillator LCT, the excitation of the oscillator LCT is done at an instant separated from the beginning of the capture phase CAP by the duration iCAP, which could be null.

During the capture phase CAP with the oscillator LCT, as long as the oscillator LCT is selected by circuit CTRL via the circuit GPIO3, each oscillation of the oscillator LCB which exceeds the threshold VTH is detected by the circuit CTRL, based on the switching of the output of the circuit COMP. For example, the circuit CTRL is configured to count a number of switching, or pulses, of the output of the comparator COMP, this number being representative of the number CNT of oscillations which have exceeded the threshold VTH. Counting number CNT, for example, corresponds to the sensing phase of the capture phase CAP.

At the end of the capture phase CAP done with the oscillator LCB, the circuit CTRL unselects the oscillator LCB, for example by changing the state of the signal analog123.

According to one embodiment, the circuit CTRL is configured to compare a threshold THT with the number CNT counted during the capture phase CAP with the oscillator LCT. Based on this comparison, the circuit CTRL is configured to determine whether oscillator LCT is facing or not a metallic surface, or, in other words, whether a tamper is detected or not.

At the end of the capture phase CAP done with the oscillator LCT, the circuit CTRL unselects the oscillator LCT, for example by changing the state of the signal analog123.

According to one embodiment, each capture phase CAP has a duration TCAP. The duration TCAP comprises the duration iCAP, which could be null.

According to one embodiment, each measurement phase MEAS comprises a non-null temporization duration TEMPO between the ends of its last capture phase CAP and the end of the measurement phase MEAS. According to an alternative embodiment, the temporization duration TEMPO is null, or, in other words, is omitted. In this last case, each measurement phase MEAS ends when all its capture phases CAP have been done.

According to one embodiment, as long as the circuit CTRL is activated, the circuit CTRL is configured to implements a plurality of successive measurement phases MEAS. In this case, each time a measurement phase MEAS ends, the circuit CTRL controls the beginning of a next measurement phase MEAS.

According to one embodiment, the circuit CTRL is configured to wake up the system 5. For example, in order to wake-up the system 5, the circuit CTRL sends a wake-up signal or wake-up event WU to the circuit PM, which, in result of receiving the wake-up event WU, switches-on the power supply of the microcontroller μC, or, in other words, the power supply of the voltage domain comprising the microcontroller PC.

According to one embodiment, once the microcontroller is supplied after a wake-up event WU sent by the circuit CTRL, the microcontroller μC may deactivate the circuit CTRL, for example by changing the state of the bit EN.

According to one embodiment, each time the circuit CTRL sends a wake-up event WU to the circuit PM, the circuit CTRL may associate an interrupt IT to the wake-up event. Thus, once switched-on, the microcontroller μC may read from the circuit CRTL the interrupt IT associated to the wake-up event WU. In result of detecting an interrupt IT associated to a wake-up event WU, the microcontroller μC may read information in the circuit CTRL, for example in register(s) of the circuit CTRL, which corresponds to the interrupt IT. This information indicates, for example, whether a tamper has been detected and/or whether a number of clockwise or anticlockwise revolutions of the wheel 1 has reached a corresponding target value.

For example, the circuit CTRL wakes up the system 5 with a wake-up event WU and associates a corresponding interrupt IT with this wake-up event WU when a tamper is detected.

As a complementary or alternative example, the circuit CTRL wakes up the system 5 with a wake-up event WU and associates a corresponding interrupt IT with this wake-up event WU when the number of clockwise revolutions of the wheel 1 reaches a threshold and/or when the number of anti-clockwise revolutions of the wheel 1 reaches a threshold.

In system 5, the microcontroller μC is be powered down for the whole duration of at least one measurement phases MEAS, or, in other words, during the whole duration of one measurement phase MEAS or during the whole duration of a plurality of successive measurement phases MEAS. This allows reducing the power consumption of the system 5 compared to known systems for measuring damping times of the oscillators LCA, LCB and LCT. In particular, during a given measurement phase MEAS, for each oscillator LCA, LCB and LCT which is excited and sensed during this given phase MEAS, the microcontroller μC is off during the corresponding excitation phase and the corresponding sensing phase.

According to one embodiment, when the system 5 is in low power mode, the circuit CTRL receives a clock signal Lclk, which has a frequency lower than a clock signal clk used by the microcontroller μC. For example, the signal clk has a frequency of several MHz, for example of several dozens of MHz, whereas the signal Lclk has a frequency of several KHz, for example of several dozens of KHz, for example a frequency approximatively equal to 37 KHz. Preferably, in low power mode, the signal clk is switched off. Preferably, all the durations described above, as for example the duration iCAP and/or the duration TCAP and/or the duration of each measurement phase MEAS and/or the duration TEMPO are expressed as a number of periods of the signal Lclk.

According to one embodiment, at least one of the values and/or durations described above are configurable and may be set by the microcontroller PC, for example, during a programming step implemented by the microcontroller μC before activating the circuit CTRL. For example, at least one of the following values and durations is configurable and set by the microcontroller μC:

the value of the threshold VTH,

the value of the threshold THAB,

the value of the threshold THT,

the duration TP of the pulse Psig,

the value of the bias potential VPOL,

the duration TCAP of each capture phase CAP,

the duration of the measurement phases MEAS, or, in other words, the value of the temporization duration TEMPO, and

the duration iCAP.

For example, the duration TP of the pulse Psig is determined based on the values of the capacitive components and of the inductive components of the LC oscillators. For example, the duration TP is determined for reducing the current in the corresponding circuit GPIO during the excitation phase, while maximizing the amplitude of the free oscillations of the corresponding oscillator.

For example, each configurable value or duration is stored in a register, which is for example written by the microcontroller μC before activating circuit CTRL and switching in sleep mode.

According to an alternative embodiment, the above described values and durations all have a fixed or constant value, these fixed values being, for example, stored in a non-volatile memory.

According to one embodiment, the comparator COMP is not only used during the measurement phases MEAS by the circuit CTRL, but also, when the circuit CTRL is deactivated, by the microcontroller μC, and, more generally by other applications of the system 5. In such an embodiment, the comparator COMP may, for example, operate in nominal power supply mode and in low power supply mode. In this case, the microcontroller μC is, for example, configured to configure the comparator COMP to operate in low power supply mode before activating the circuit CTRL. This is for example done by providing, with the microcontroller PC, a corresponding configuration signal to the circuit COMP, for example by writing with the microcontroller μC the configuration signal in a configuration register of circuit COMP.

According to one embodiment, what has been described in the previous paragraph for the comparator COMP may be applied for the circuit 130 and/or the circuit 140.

For example, circuit 130 is not only used during the measurement phases MEAS by the circuit CTRL, but also, when the circuit CTRL is deactivated, by the microcontroller μC, and, more generally by other applications of the system 5. For example, in such a case, the circuit 130 may, for example, operate in nominal power supply mode and in low power supply mode. The microcontroller μC is then, for example, configured to configure the circuit 130 to operate in low power supply mode before activating the circuit CTRL. This is for example done by providing, with the microcontroller μC, a corresponding configuration signal to the circuit 130, for example by writing with the microcontroller μC the configuration signal in a configuration register of circuit 130.

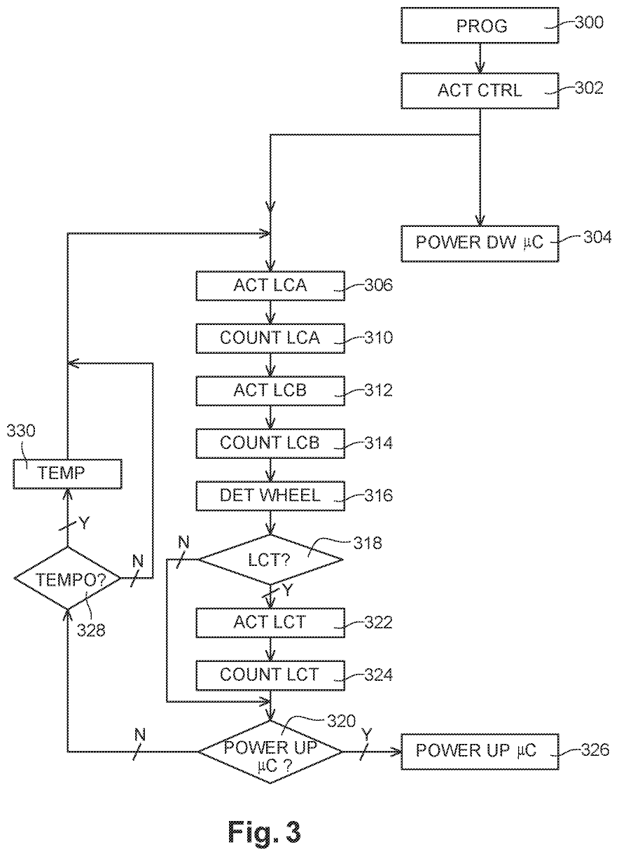

FIG. 3 illustrates an example of a method according to one embodiment, the method being implemented in an electronic system of the type described in relation with FIG. 2. For example, in the description made in relation with FIG. 3, it is considered that the method is implemented in the system 5 of FIG. 2. The method is, for example, a method for successively exciting the LC oscillators of the system 5 and for evaluating the damping time of these oscillators, for example by comparing the damping time of each oscillator with a corresponding threshold.

At an optional step 300 (block “PROG”), the microcontroller μC programs at least one of the values and/or durations described above. In other words, at step 300, the configurable value(s) and/or duration(s) of the system 5 are set by the microcontroller PC.

For example, the microcontroller μC programs the value of the threshold VTH and/or the value of the bias potential VPOL, for example in a register controlling the circuit 130.

For example, the microcontroller μC programs the value of the duration of the pulse sigP, for example in a register controlling the circuit 140.

For example, the microcontroller μC programs, for example in a register controlling the circuit CTRL, the value of the threshold THAB and/or the value of the threshold THT and/or the value of the duration of each measurement phase MEAS and/or the duration TCAP and/or the value of the inter-capture duration iCAP and/or the target value(s) for the number of revolutions of the wheel 1.

Step 300 is followed by a step 302 (block “ACT CTRL”).

At step 302, the microcontroller μC activate the circuit CTRL, for example as described previously in relation with FIG. 2.

Step 302 is followed by a step 304 (block “POWER DW μC”) and a step 306 (block “ACT LCA”).

At step 304, the microcontroller μC is switched-off by the circuit PM which switches the system 5 in low power mode, as previously described in relation with FIG. 2.

At step 306, the circuit CTRL controls the application of an excitation signal to the oscillator LCA via the circuit GPIO1. The beginning of step 306 corresponds to the beginning of a capture phase CAP with the oscillator LCA.

In this example, the oscillator LCA is selected by circuit CTRL simultaneously to the beginning of step 306. This is done by controlling in consequence the circuit GPIO1, for example with signal analog123, so that its terminal 103 and 106 are coupled with each other.

Further, in this example where the oscillator LCA is the first oscillator selected during each measurement phase MEAS, the beginning of step 306 further corresponds to the beginning of a corresponding measurement phase MEAS.

According to one embodiment, at step 306, before controlling the application of the excitation signal to oscillator LCA, circuit CTRL for example waits for the duration iCAP.

Step 306 is followed by a step 310 (block “COUNT LCA”). During this step 310, the circuit CTRL counts the number of switching of the output of the comparator COMP, or, in other words, counts the number CNT of oscillations in the oscillator LCA which reaches the threshold VTH. At the end of the step 310, the circuit CTRL deselects the oscillator LCA, for example with signal analog123, so that oscillator LCA is no longer coupled to comparator COMP.

The steps 306 and 310 correspond to a capture phase CAP with the oscillator LCA, the capture phase CAP having a duration, for example, equal to TCAP.

Step 310 is followed by a step 312 (block “ACT LCB”). At step 312, the circuit CTRL controls the application of an excitation signal to the oscillator LCB via the circuit GPIO2. The beginning of step 312 corresponds to the beginning of a capture phase CAP with the oscillator LCB.

In this example, the oscillator LCB is selected by circuit CTRL simultaneously to the beginning of step 312. This is done by controlling in consequence the circuit GPIO2, for example with signal analog123, so that its terminal 103 and 106 are coupled with each other.

According to one embodiment, at step 312, before controlling the application of the excitation signal to oscillator LCB, circuit CTRL for example waits for the duration iCAP.

Step 312 is followed by a step 314 (block “COUNT LCB”). During this step 314, the circuit CTRL counts the number of switching of the output of the comparator COMP, or, in other words, counts the number CNT of oscillations in the oscillator LCB which reaches the threshold VTH. At the end of the step 314, the circuit CTRL deselects the oscillator LCB, for example with signal analog123, so that oscillator LCB is no longer coupled to comparator COMP.

The steps 312 and 314 correspond to a capture phase CAP with the oscillator LCB, the capture phase CAP having a duration, for example, equal to TCAP.

In the example of FIG. 3, the set of steps 306, 310, 312, 314 is followed by a step 316 (block “DET WHEEL”), which consists, based on the results of steps 310 and 314, to determine the position of the wheel 1 (FIG. 1).

In the example of FIG. 3, step 316 is followed by a step 318 (block “LCT?”), which consists in determining, with circuit CTRL, whether a tamper detection is required, or, in other words, whether a capture phase CAP with the oscillator LCT is should be done in the current measurement phase MEAS.

In an alternative example, the step 316 and 318 are implemented in parallel so that, when a tamper detection is required, the capture phase CAP with oscillator LCT begins when the previous capture phase CAP ends.

If no tamper detection has to be implemented (branch N of block 318), step 318 is followed by a step 320 (block “POWER UP μC”).

If a tamper detection has to be implemented (branch Y of block 318), step 318 is followed by a step 322 (block “ACT LCT”).

At step 322, the circuit CTRL controls the application of an excitation signal to the oscillator LCT via the circuit GPIO3. The beginning of step 322 corresponds to the beginning of a capture phase CAP with the oscillator LCT.

In this example, the oscillator LCT is selected by circuit CTRL simultaneously to the beginning of step 322. This is done by controlling in consequence the circuit GPIO3, for example with signal analog123, so that its terminal 103 and 106 are coupled with each other.

According to one embodiment, at step 322, before controlling the application of the excitation signal to oscillator LCT, circuit CTRL for example waits for the duration iCAP.

Step 322 is followed by a step 324 (block “COUNT LCT”). During this step 324, the circuit CTRL counts the number of switching of the output of the comparator COMP, or, in other words, counts the number CNT of oscillations in the oscillator LCT which reaches the threshold VTH. At the end of the step 324, the circuit CTRL deselects the oscillator LCT, for example with signal analog123, so that oscillator LCT is no longer coupled to comparator COMP.

The steps 322 and 324 correspond to a capture phase CAP with the oscillator LCT, the capture phase CAP having a duration, for example, equal to TCAP.

Step 324 is followed by step 320.

At step 320, the circuit CTRL determines whether the microcontroller μC should be woken up. In other words, at step 320, circuit CTRL determines whether a wake-event WU should be sent to the circuit PM.

For example, the circuit CTRL determines, based on the position of the wheel 1 determined for each of a plurality of successive measurement phases MEAS, the number of clockwise revolutions and/or the number of anti-clockwise revolutions of the wheel 1 since the circuit CTRL has been activated by the microcontroller. Then, these numbers of revolutions are compared with target values, for example to determine whether the number of clockwise revolutions has reached a target value and/or whether the number of anti-clockwise revolutions has reached a target value. If this is the case, the circuit CTRL, for example, sends a wake-up event to the circuit PM in order to wake-up the microcontroller PC. Preferably, when sending the wake-up event to the circuit PM, the circuit CTRL further associates a corresponding interrupt to this wake-up event, for example to indicate to the microcontroller μC that the number of clockwise revolutions has reached a target value or that the number of anti-clockwise revolutions has reached a target value.

For example, in case a tamper detection has be performed, the circuit CTRL determines, based on the number counted at step 324, whether the oscillator LCT is facing a metallic surface which is indicative of a tamper. If the oscillator LCT is facing a metallic surface (a tamper is detected), the circuit CTRL, for example, sends a wake-up event to the circuit PM in order to wake-up the microcontroller μC. Preferably, when sending the wake-up event to the circuit PM, the circuit CTRL further associates a corresponding interrupt to this wake-up event, for example to indicate to the microcontroller μC that a tamper has been detected.

If the microcontroller μC has to be woken up (branch Y of the block 320), step 320 is followed by a step 326 (block “POWER UP μC”). At step 326, the microcontroller is woken up. For example, at step 326, the circuit CTRL sends a wake-up signal WU to the circuit PM, which then turns on the power supply of the microcontroller μC. Further, at step 326, the circuit CTRL, for example, associates an interrupt IT to the wake-up event WU for indicating to the microcontroller μC why the circuit CTRL asked for the microcontroller intervention. For example, once the microcontroller μC is woken-up, it deactivates the circuit CTRL. For example, once woken-up, the microcontroller μC detects or reads the interrupt IT associated to the wake-up event WU sent by the circuit CTRL.

If there is no need to wake-up the microcontroller μC (branch N of block 320), step 320 is followed by a step 328 (block “TEMPO?”).

At step 328, the circuit CTRL determines whether the current measurement phase MEAS is finished. In other words, the circuit CTRL determines whether a temporization duration TEMPO should elapse before controlling the beginning of the next measurement phase MEAS.

If the measurement phase MEAS is finished (branch N of block 328), step 328 is followed by step 306, and the next measurement phase MEAS begins.

If the measurement phase MEAS is not finished (branch Y of block 328), step 328 is followed by a step 330 (block “TEMP”).

At step 330, circuit CTRL waits until the end of the current measurement phase MEAS, or, in other words, wait for the duration TEMPO to be elapsed. Once the current phase MEAS is over, step 330 is followed by step 306, and the next phase MEAS begins.

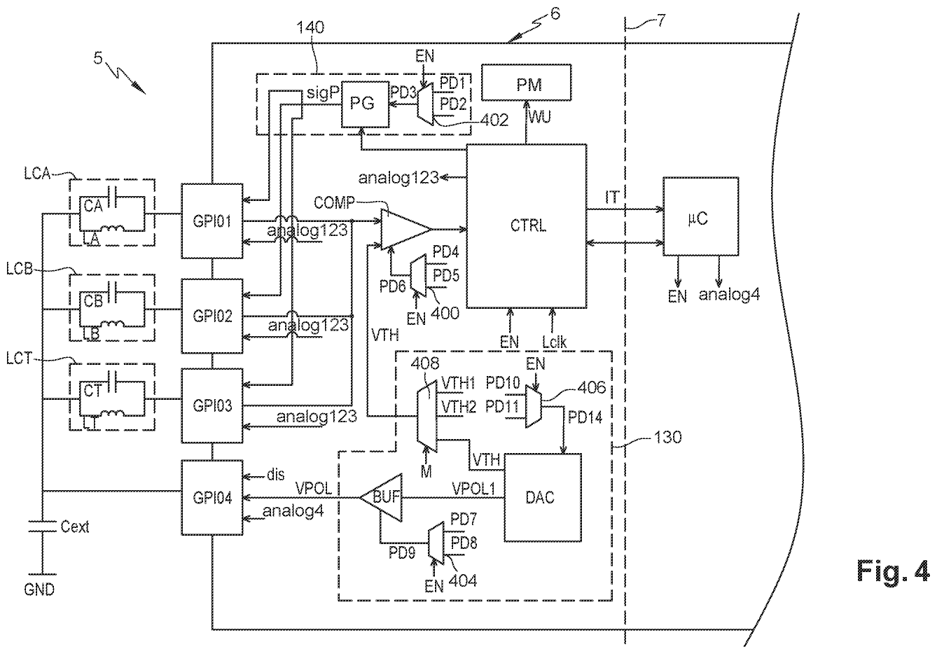

Those skilled in the art are capable of modifying the order and/or the number of the steps described in relation with FIG. 4.

For example, a step similar to step 320 may be implemented after steps 306, 310, 312 and 314, to determine whether the microcontroller μC has to be woken up, for example because the number of revolutions of the wheel 1 has reached the target value, or whether the method should continue at step 318.

For example, steps 306 and 310 may be permuted with steps 312 and 314 respectively. In this case, if step 302 is followed by step 312 rather than step 306, the measurement phase MEAS begins with step 312.

For example, step 316 may be implemented just before step 320, or in step 320.

For example, steps 318, 322 and 324 may be implemented before steps 306, 310, 312, 314. In this case, the measurement phase MEAS begins with step 312.

For example, steps 318, 322 and 324 may be implemented between steps 306, 310 and steps 312, 314.

For example, in one embodiment where the system 5 does not comprise the oscillator LCT, steps 318, 322 and 324 may be suppressed.

For example, in one embodiment, the step 318 is such that steps 322 and 324 are performed every X measurement phases MEAS, with X an integer superior or equal to one. For example, the value X may be programmed by the microcontroller PC, for example in a register, at step 300, or may be a constant and fixed value. In an alternative embodiment, the steps 322 and 324 are performed at each measurement phase MEAS.

Other examples of modifying the number and/or the order of the steps of the above-described method will be apparent for those skilled in the art in view of the above description.

In view of the description made in relation with FIGS. 2 and 3, it follows that the more the temporization TEMPO is, the less the frequency of the measurement phases MEAS. In other words, the more the duration of the measurement phases MEAS is, the less the frequency of the measurement phases MEAS.

According to one embodiment where the duration of the measurement phases MEAS, or, in other words, the value of the duration TEMPO, is a value programmed by the microcontroller μC before activating the circuit CTRL, for example at step 300, the microcontroller μC may be configured to adapt the duration of the phases MEAS to the speed of rotation of the wheel 1. For example, the microcontroller μC is configured to increase, respectively decrease, the duration of the measurement phases MEAS when the speed of rotation of the wheel 1 decreases, respectively increases. Increasing the duration of the measurement phases MEAS when the speed of rotation of the wheel 1 decreases allows for reducing the frequency of the measurement phase MEAS. Decreasing the frequency of the measurement phase MEAS with the decrease of the speed of rotation of the wheel 1 allows to avoid useless measurement phases MEAS. A measurement phase MEAS is considered as being useless, for example, if the position of the wheel 1 determined during this measurement phase MEAS is the same that the position of the wheel 1 determined at the previous measurement phase MEAS. Avoiding useless measurement phases MEAS allows for reducing the consumption of the system 5.

In the description made in relation with FIGS. 2 and 3, the circuits 130, 140 and COMP are always active, or, in other words, enabled.

According to one embodiment, at least one of the circuits 130, 140 and COMP may be deactivated, or, in other words, disabled, by the circuit CTRL when circuit CTRL is active. In case the circuit CTRL is active, it has the priority over the microcontroller μC to enable and disable these circuits. In particular, the circuit CTRL may disable at least one of the circuits 130, 140 and COMP during step 330. For example, disabling at least one of the circuits 130, 140 and COMP means that this circuit will not receive the clock signal Lclk and/or that this circuit will deactivate its outputs and/or that this circuit will open at least one of its internal switches to be disconnected from the power supply.

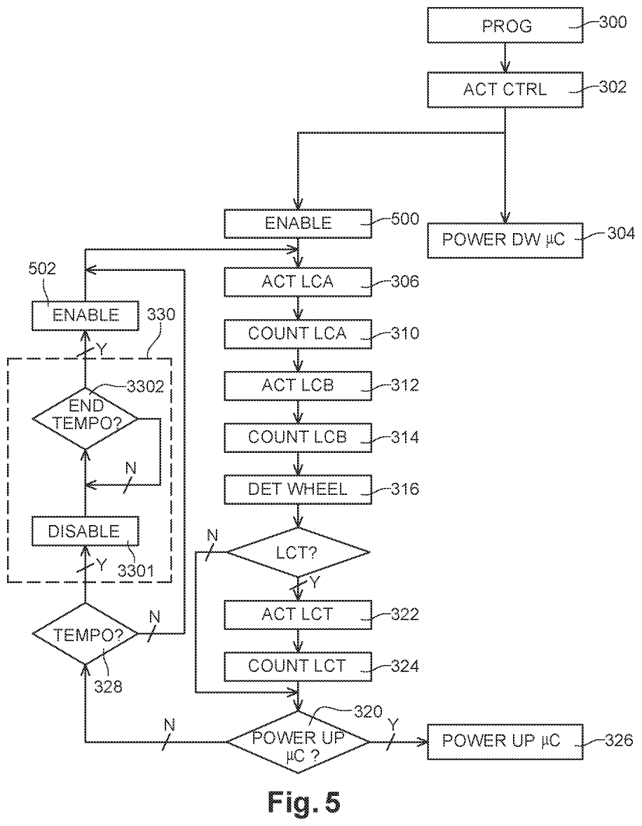

Disabling at least one of the circuits 130, 140 and COMP with the circuit CTRL during a part of the duration of each measurement phase MEAS allows further reducing the consumption of the system 5. An example of such an embodiment will be now described in relation with FIGS. 4 and 5.

FIG. 4 illustrates an example of the electronic system 5 according to one other embodiment.

In this example, each of the circuits COMP, 130 and 140 may be selectively disabled by the active circuit CTRL. In alternative examples not shown, only one or two of these circuits 130, 140 and COMP may be disabled by the active circuit CTRL.

In this example, each of the circuits COMP, 130 and 140 may also be disabled by the microcontroller μC, only when the circuit CTRL is not activated. In other words, when activated, the circuit CTRL has priority over the microcontroller μC for controlling the enabling and the disabling of each of the circuits COMP, 130 and 140.

The system 5 of FIG. 4 comprises all the circuits and the components of the system 5 described in relation with FIG. 2.

In the example of FIG. 4 where the circuit COMP can be enabled and disabled by the active circuit CTRL, the circuit CTRL is configured to provide a signal PD4 to the circuit COMP. The signal PD4 controls, when the circuit CTRL is active, whether the circuit COMP is active or not.

Further, in the example of FIG. 4, the circuit COMP can be enabled and disabled by the microcontroller μC when the circuit CTRL is not active, and the circuit COMP receives a signal PD5 provided by the microcontroller μC. The signal PD5 controls, when the circuit CTRL is not active, whether the circuit COMP is enabled or not.

For example, signals PD4 and PD5 are received by a routing circuit 400 controlled by the bit EN. Circuit 400 provides a signal PD6 which controls whether the circuit COMP is enabled or not. Signal PD6 is equal to signal PD4 when circuit CTRL is active, and to signal PD5 when circuit CTRL is not active.

In the example of FIG. 4 where circuit 140 can be enabled and disabled by the active circuit CTRL, the circuit CTRL is configured to provide a signal PD1 to the circuit 140, for example to the circuit PG of circuit 140. The signal PD1 controls, when the circuit CTRL is active, whether the circuit 140, for example its circuit PG, is enabled or not.

Further, in the example of FIG. 4, the circuit 140 can be enabled and disabled by the microcontroller μC when the circuit CTRL is not active, and the circuit 140, for example its circuit PG, receives a signal PD2 provided by the microcontroller PC. The signal PD2 controls, when the circuit CTRL is not active, whether the circuit 140, for example its circuit PG, is enabled or not.

For example, circuit 140 comprises a routing circuit 402. The circuit 402 receives signals PD1 and PD2 and is controlled by the bit EN. Circuit 402 provides a signal PD3 which controls whether the circuit 140, for example its circuit PG, is enabled or not. Signal PD3 is equal to signal PD1 when circuit CTRL is active, and to signal PD2 when circuit CTRL is not active.

In the example of FIG. 4, the circuit 130 comprises at least one digital to analog converter DAC configured to provide the threshold VTH and the bias potential VPOL. Further, in this example, the circuit 130 comprises an optional buffer circuit BUF receiving the potential VPOL from the converter DAC and providing the potential VPOL to circuit GPIO4. The circuit 130 of FIG. 2 may be identic to the one represented in FIG. 4.

In one embodiment, the circuit BUF may be enabled and disabled by the active circuit CTRL. As an example, circuit BUF may also be enabled and disabled by the microcontroller μC, only when the circuit CTRL is not activated. In other words, when activated, the circuit CTRL has priority over the microcontroller μC for controlling the enabling and the disabling of the circuit BUF.

In one embodiment, the circuit DAC may be enabled and disabled by the active circuit CTRL. As an example, circuit DAC may also be enabled and disabled by the microcontroller μC, only when the circuit CTRL is not activated. In other words, when activated, the circuit CTRL has priority over the microcontroller μC for controlling the enabling and the disabling of the circuit DAC.

In one embodiment, as it is the case in the example of FIG. 4, both the circuits BUF and DAC of circuit 130 can be enabled and disabled by the active circuit CTRL. The circuit CTRL is then, for example, configured to provide a signal PD7 to the circuit BUF and a signal PD10 to the circuit DAC. The signal PD7 controls, when the circuit CTRL is active, whether the circuit BUF is enabled or not. The signal PD10 controls, when the circuit CTRL is active, whether the circuit DAC is enabled or not.

Further, in the example of FIG. 4, both circuits BUF and DAC of circuit 130 can be enabled and disabled by the microcontroller μC when the circuit CTRL is not active, the circuit BUF receives a signal PD8 provided by the microcontroller μC and the circuit DAC receives a signal PD11 provided by the microcontroller μC. The signal PD8 controls, when the circuit CTRL is not active, whether the circuit BUF is enabled or not. The signal PD11 controls, when the circuit CTRL is not active, whether the circuit DAC is enabled or not.

For example, circuit 130 comprises a routing circuit 404 receiving the signals PD7 and PD8 and providing a signal PD9 to circuit BUF. The routing circuit 404 is configured, for example by being controlled by the bit EN, so that signal PD9 is equal to signal PD7 when circuit CTRL is active, and to signal PD8 when circuit CTRL is not active.

For example, circuit 130 comprises a routing circuit 406 receiving the signals PD10 and PD11 and providing a signal PD12 to circuit DAC. The routing circuit 406 is configured, for example by being controlled by the bit EN, so that signal PD12 is equal to signal PD10 when circuit CTRL is active, and to signal PD11 when circuit CTRL is not active.

In alternative examples, for example alternative examples where the circuit 130 is not implemented as represented on FIG. 4, the circuit 130 can be enabled and disabled by the active circuit CTRL using only one signal provided by the circuit CTRL to the circuit 130. Further, if circuit 130 can be also enabled and disabled by the microcontroller μC when the circuit CTRL is not active, the circuit 130 can be enabled and disabled by the microcontroller μC while circuit CTRL is not active, by using only one signal provided by the microcontroller to the circuit 130. In the example of the circuit 130 shown in FIG. 4, this corresponds to a case where signals PD10 and PD7 are merged, signals PD11 and PD8 are merged, and signals PD9 and PD12 are merged.

In one example, as it could be also the case in FIG. 2, the circuit 130 may be also used, when the circuit CTRL is not active, to provide a threshold signal to the comparator COMP which could be different from the threshold signal VTH. Thus, the comparator COMP may be used, when the circuit CTRL is not active, to compare a received signal with a threshold signal which may be different from the threshold VTH.

For example, the circuit 130 may comprise a routing circuit 408 controlled by a signal M. The signal M is, for example, provided by the microcontroller PC, for example by being written in a register by the microcontroller μC. The circuit 408 receives the output of the circuit DAC on which threshold VTH is available when circuit CTRL is active, and at least another threshold signal, for example two threshold signals VTH1 and VTH2 in FIG. 4. When the circuit CTRL is active, the signal provided by the circuit 408 to the comparator COMP corresponds to the threshold VTH. This configuration of the circuit 408 is controlled by the signal M. When the circuit CTRL is not active, depending on the signal M, the signal provided by circuit 408 to circuit COMP may be any one of the threshold signals received by the circuit 408.

According to one embodiment, when a measurement phase MEAS comprises a temporization TEMPO which is not null, the circuit CTRL disables the circuit COMP and/or the circuit 130 and/or the circuit 140 at the beginning of the temporization TEMPO, and enables these circuits at the end of the temporization TEMPO and, preferably, at the beginning of each measurement phase MEAS. This allows to further decrease the consumption of the system 5.

Those skilled in the art are capable of adapting the above description made in relation with FIG. 4 to embodiments where circuits 130 and COMP are dedicated for the method of determining the position of the wheel 1, for example by suppressing the routing circuits 408 and signals M.

Those skilled in the art are also capable of adapting the above description made in relation with FIG. 4 to embodiments where at least one of the circuits 130, 140 and COMP which could be enabled and disabled by circuit CTRL cannot be enabled and disabled by the microcontroller μC, and/or to embodiments where at least one of the circuits 130, 140 and COMP which could be enabled and disabled by the microcontroller μC cannot be enabled and disabled by the circuit CTRL.

FIG. 5 illustrates an example of a method according to one other embodiment, the method being implemented in an electronic system of the type described in relation with FIG. 4. As an example, in the description made in relation with FIG. 5 it is considered that the method is implemented in the system 5 of FIG. 4.

The method of FIG. 5 comprises all the steps of the method of FIG. 3.

In FIG. 5, the method further comprises a step 500 (block “ENABLE”). Step 500 is implemented after step 302, and before the first measurement phase MEAS begins. For example, in the example of FIG. 5 where each measurement phase MEAS begins at step 306, the step 500 is implemented between steps 304 and 306.

Step 500 consists of enabling, with the active circuit CTRL, the circuit 130. Once circuit 130 is enabled, the potential VPOL is applied to the capacitor Cext by the circuit GPIO4 and the circuit 130 provides the threshold VTH to the comparator COMP. More generally, step 500 for example consists in enabling each of the circuits 130, 140 and COMP when the microcontroller μC activates the circuit CTRL.

According to one embodiment, step 500 has a duration Init, which is long enough to ensure the correct enabling of the circuit 130, or, in other words, to ensure that voltage across the capacitor Cext reaches the value of potential Vpol. The duration Init may be programmed at step 300 by the microcontroller μC, or may be a constant value. For example, the duration Init corresponds to a given number of periods of the signal Lclk.

Further, step 330 of FIG. 5 comprises successive steps 3301 (block “DISABLE”) and 3302 (block “END TEMPO?”).

Step 3301 consists in disabling all the circuits COMP, 130 and 140 which can be disabled by the active circuit CTRL.

Step 3302 consists in waiting the end of the temporization TEMPO. During the whole duration of the step 3302, as at least some of the circuits 130, 140 and COMP are disabled, the power consumption of system 5 is reduced.

In FIG. 5, step 3302, and thus 330, are followed by a step 502 (block “ENABLE”). Step 502 is done once step 330 is finished, or, in other words, once the temporization TEMPO has elapsed, but before the next measurement phase MEAS begins. Step 502 consists in enabling, with the circuit CTRL, all the circuits which have been disabled at the previous step 3301.

According to one embodiment, step 502 has a duration Recovery, which is long enough to ensure the correct enabling of the circuit 130, or, in other words, to ensure that voltage across the capacitor Cext reaches the value of potential Vpol. The duration Recovery may have a configurable value programmed at step 300 by the microcontroller PC, for example in a register, or may have a constant value. For example, the duration Recovery corresponds to a given number of periods of the signal Lclk.

The end of the step 502 here corresponds to the end of the current measurement phase MEAS and to the beginning of the next measurement phase MEAS. In the example of FIG. 5, step 502 is followed by step 306.

The order and/or the number of steps of the method of FIG. 5 may be modified by those skilled in the art, for example, in a similar manner to what has been described in relation with FIG. 3.

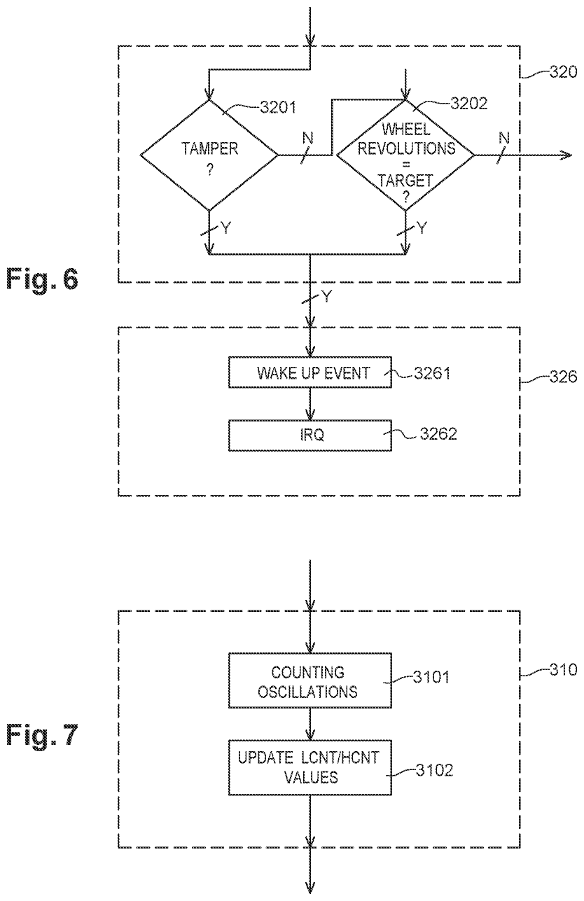

FIG. 6 illustrates an example of the steps 320 and 326 of the methods of FIGS. 3 and 5 according to one embodiment.

In the example of FIG. 6, step 320 comprises two steps 3201 (block “TAMPER?”) and 3202 (block “WHEEL REVOLUTIONS=TARGET?”).

Step 3201 consists in determining whether a tamper is detected. Step 3201 for example consists in comparing the number CNT of oscillations of the oscillator LCT which have exceeded the threshold VTH (step 324 of FIGS. 3 and 5), with the threshold THT as previously discussed.

If a tamper is detected (branch Y of blocks 3201 and 320), step 320 is followed by step 326.

If no tamper is detected (branch N of block 3201), step 3201 is followed by step 3202.

Step 3202 consists in determining whether a number of revolutions of the wheel 1 has reached a target value. If the number of revolutions of the wheel 1 has reached the target value (branch Y of blocks 3202 and 320), step 320 is over and is followed by step 326. If not (branch N of blocks 3202 and 320), step 320 is over and is followed by step 328 (see FIGS. 3 and 5). The target value may be a constant value, or may be configurable value programed by the microcontroller μC at step 300, for example in a register.

For example, step 3202 consists in determining whether a number of clockwise revolutions of the wheel 1 has reached a first target value. The first target value may be a constant value, or may be a configurable value programed by the microcontroller μC at step 300, for example in a register.

In an alternative example, step 3202 consists in determining whether a number of anti-clockwise revolutions of the wheel 1 has reached a second target value. The second target value may be a fixed value, or may be programed by the microcontroller μC at step 300, for example in a register.

In another alternative example, step 3202 consists in determining whether a number of clockwise revolutions of the wheel 1 has reached the first target value and whether a number of anti-clockwise revolutions of the wheel 1 has reached the second target value.

Those skilled in the art are capable of modifying the order and/or the number of the steps in the step 320. For example, although in the example of FIG. 6 the step 3201 is done before step 3202, in an alternative example, step 3202 is done before step 3201. In another alternative example, steps 3201 and 3202 are done simultaneously rather than sequentially.

Independently to what has been described in relation with step 320 of FIG. 6, in the example of FIG. 6, step 326 comprises two successive steps 3261 (block “WAKE UP EVENT”) and 3262 (block “IRQ”).

Step 3261 consists of sending, with circuit CTRL, a wake-up signal WU to circuit PM, so that the circuit PM switches on the microcontroller μC.

Step 3262 consists of associating, with circuit CTRL, a corresponding interrupt IT with the wake-up event WU sent by the circuit CTRL, so that the microcontroller μC knows it has been woken-up by the circuit CTRL, and, preferably, why the circuit CTRL decided to wake-up the microcontroller μC.

The operation of the system 5 described in relation with FIGS. 2 to 6 may change over time, for example because of modifications of its environment and/or by aging and/or by the temperature. These modifications of the operating conditions of the system 5 may affect and change the damping time of the LC oscillators of the system 5.

According to one embodiment, the system 5 is configured to detect a drift in the damping time of its LC oscillators, and to adapt in consequence the operation of the system 5, for example by adapting the value of the threshold VTH.

For example, in such an embodiment, each time a number CNT of oscillations reaching the threshold VTH is counted, for example in steps 310, 314, 324, the system 5 is configured to determine whether this number CNT is superior to a boundary value BMIN and inferior to a high boundary value BMAX. If the counted number is below the value BMIN or above the value BMAX, this is an indication of a drift in the operating conditions of the system 5. Based on this indication, the microcontroller μC, for example, adapts the value of the threshold VTH and/or the value BMIN and/or the value BMAX.

According to one embodiment, the boundaries BMAX and BMIN have configurable values. These configurable values are, for example, programmed by the microcontroller PC, for example at step 300, for example in a register. According to an alternative embodiment, these values BMIN and BMAX may be constant values.

According to one embodiment, each time a number CNT of oscillations reaching the threshold VTH is counted, for example in steps 310, 314, 324, the system 5 is configured to update a value LCNT with the number CNT if the number CNT is below the current value LCNT and to update a value HCNT with the number CNT if the number CNT is above the current value HCNT. The values LCNT and HCNT are for example memorized in a register.

According to one embodiment, the circuit CTRL is configured to detect, for example in step 320, that the value LCNT is below the value BMIN or that the value HCNT is above the value BMAX. Preferably, the circuit CTRL is further configured, for example at step 326, to wake-up the microcontroller μC by sending a wake-up event WU to the circuit PM, and to associate a corresponding interrupt IT with this wake-up event WU. The interrupt IT for example indicates to the microcontroller μC that the value LCNT is below the value BMIN or that the value HCNT is above the value BMAX.

According to an alternative embodiment, each time the microcontroller μC is woken-up by the circuit CTRL by sending a wake-up event WU to the circuit PM, the microcontroller μC is configured to read the values LCNT and HCNT, to compare the value LCNT with the boundary BMIN, to compare the value HCNT with the boundary BMAX, and, based on these comparisons, to detect a drift in the operating conditions of the system 5.

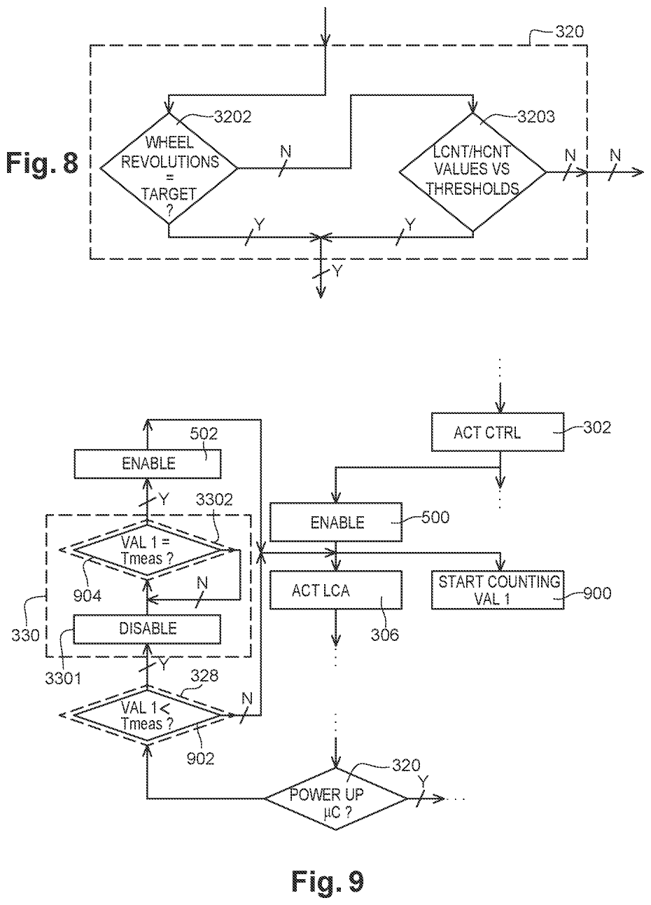

FIGS. 7 and 8 illustrate an example of an embodiment where the system 5 is configured to detect a drift in the damping time of its LC oscillators, using the boundary values BMIN and BMAX and the values LCNT and HCNT.

More particularly, FIG. 7 illustrates an example of a step where a number CNT of oscillations exceeding the threshold VTH is counted, and, more particularly, an example of the step 310, being understood that steps 314 and 324 may be similar to that step 310.

In the example of FIG. 7, step 310 comprises two successive steps 3101 (block “COUNTING OSCILLATIONS”) and 3102 (block “UPDATE LCNT/HCNT VALUES”).

At step 3101, the circuit CTRL counts, based on the output of the circuit COMP, the number CNT of oscillations reaching the threshold VTH. As FIG. 7 refers to step 310, the oscillations are the ones in the oscillator LCA.

Step 3102 consists in comparing the number CNT counted at previous step 3101 with both values LCNT and HCNT, and to update the value LCNT with number CNT if number CNT is below the current value LCNT and the value HCNT with number CNT if number CNT is above the current value HCNT. Step 3102 is here implemented by circuit CTRL.

FIG. 8 illustrate an example of the step 320 in one embodiment where the circuit CTRL is configured to send a wake-up event WU if the value LCNT is below the boundary BMIN or if the value HCNT is above the boundary BMAX. In the example of FIG. 8, the system 5 is not configured to detect a tamper, and, thus, step 320 does not comprises the step 3201 (see FIG. 6).

In FIG. 8, step 320 begin with the step 3202 (see FIG. 6).

If the number of revolutions of the wheel 1 has reached the target value (branch N of blocks 3202 and 320), steps 3202 and 320 are over and followed by step 326 (see FIGS. 3, 5 and 6).

If the number of revolutions of the wheel 1 has not reached the target value (branch N of block 3202), step 3202 is, in this example, followed by a step 3203 (block “LCNT/HCNT VALUES VS THRESHOLDS”).

Step 3203 consists in checking whether at least one of the values LCNT and HCNT is outside the range of value from BMIN to BMAX, which indicates a drift in the operating conditions of the system 5. For example, circuit CTRL is configured to compare value LCNT with boundary BMIN and value HCNT with boundary BMAX.

If both values LCNT and HCNT are in the range of values from BMIN to BMAX (branch N of blocks 3203 and 320), both steps 3203 and 320 are over and followed by step 328 (see FIGS. 3 and 5).

If one of the values LCNT and HCNT is outside the range of values from BMIN to BMAX (branch Y of blocks 3203 and 320), steps 3203 and 320 are over and followed by step 326 (see FIGS. 3 and 5).

At step 326, the circuit CTRL sends a wake-up event WU and, for example, associates a corresponding interrupt IT with the wake-up event for indicating to the microcontroller μC that boundary BMIN or BMAX has been exceeded.

Although step 320 of FIG. 8 does not comprise step 3201, those skilled in the art are capable of implementing step 320 with any combination of steps 3201, 3202 and 3203, these steps 3201 and/or 3202 and/or 3203 being implemented simultaneously or sequentially with respect to each other.

Further, although step 3203 is here implemented in step 320, those skilled in the art are capable of implementing the step 3203 each time the values LCNT and HCNT may be updated, for example after each of steps 310, 314 and 324, rather than in step 320.

FIG. 9 illustrates an example of a method according to one embodiment, the method being implemented in a system of the type described in relation with FIG. 4.

FIG. 9 more particularly illustrates an example of how the temporization TEMPO may be implemented.

FIG. 9 comprises all the steps of the method of FIG. 5, some of these steps being not represented in FIG. 9 in order to not surcharging the Figure.

In FIG. 9, the method further comprises, at the beginning of each measurement phase MEAS, that is, after step 320 and, in the example of FIG. 9, simultaneously to the step 306, a step 900 (block “START COUNTING VAL1”).

Step 900 consist in beginning to count, from zero, a number of periods of the signal Lclk. The counted number has a value val1, which is incremented at each period of the signal Lclk.

In FIG. 9, step 328 corresponds to a step 902 (bloc “val1<Tmeas”). Step 902 consists in comparing the value val1 with a threshold value Tmeas.

If the value val1 is above the threshold Tmeas (branch N of blocks 902 and 328), there is no temporization TEMPO, or, in other words, the temporization TEMPO is null. Steps 902 and 328 are then followed by the beginning of the next measurement phase MEAS, that is to say, the steps 306 and 900 in the example of FIG. 9.

If the value val1 is below the threshold Tmeas (branch Y of blocks 902 and 328), there is temporization TEMPO which is not null. Steps 902 and 328 are then followed by step 330.

In FIG. 9, step 3302 corresponds to a step 904 (bloc “VAL1=Tmeas?”). Step 904 consists in waiting until the value val1 reaches the threshold Tmeas, or, in other words, to wait until the temporization TEMPO has elapsed.

In an alternative embodiment, rather to increment value val1 from zero, and to compare value val1 with threshold Tmeas, value val1 is initialized to the value Tmeas at step 900, and is decremented at each period of the signal Lclk. In such an embodiment, the value val1 is compared with zero at steps 902 and 904. For example, step 902 is followed by step 330 if value val1 is superior to zero and by step 900 if value val1 is equal to zero, and step 904 consists in waiting until value val1 is equal to zero.

Furthermore, those skilled in the art are capable of modifying the number and/or the order of the steps of the method of FIG. 9, for example, in a similar manner to what has been described in relation with FIG. 3. In particular, those skilled in the art are capable of adapting the method of FIG. 9 to one embodiment where the circuits COMP, 130 and 140 are always enable, for example by suppressing step 500, 502 and 3301 in the method of FIG. 9.

According to one embodiment, the threshold Tmeas has a constant value. According to an alternative embodiment, the threshold Tmeas has a configurable value, this value being, for example, programed by the microcontroller μC, for example at step 300, for example in a register. By increasing the value of the threshold Tmeas, the microcontroller may increase the duration of the temporization TEMPO, and, thus, decrease the frequency of the measurement phases MEAS.

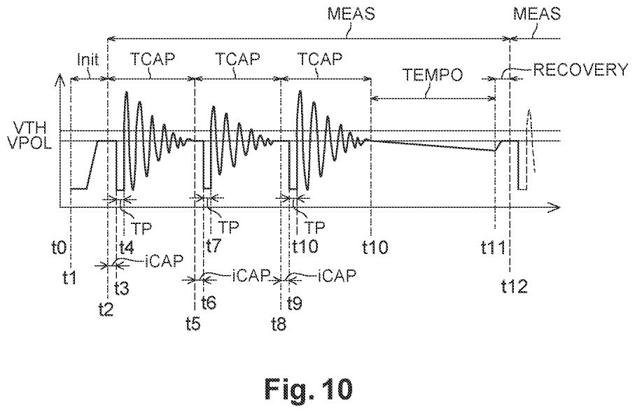

FIG. 10 is a chronogram illustrating the method of previous FIGS. 3, 5 and 9 according to one embodiment. More particularly, FIG. 10 illustrates the evolution of the voltage across the oscillators LCA, LCB, and LCT of systems 5 previously described.

At an instant t0, the microcontroller μC is active, and the circuit CTRL is inactive. The voltage domains of the chip 6 are supplied by the circuit PM.

In the example of FIG. 10, the circuit COMP, 130 and 140 may be enabled and disabled, or, in other words, activated and deactivated, by the circuit CTRL when circuit CTRL is active.

More particularly, from the instant t0 to a following instant t1, the circuit COMP, 130, and 140 are disabled. Thus, as it can be seen on FIG. 10, the voltage on the terminal 103 of the circuits GPIO1, GPIO2, GPIO3, and GPIO4, or, in other words, on nodes 101, 11 and 121 of the respective oscillator LCA, LCB and LCT is null.

Between instant t0 and t1, the microcontroller μC may program (step 300) at least some of the configurable values previously described.

Further, in this example, it is considered the case where the circuit GPIO4 is configured by the microcontroller PC. In other words, it is here considered, as an example, the case where the circuit GPIO4 is not controlled by the circuit CTRL, even when circuit CTRL is active.

Thus, between instants t0 and t1, the microcontroller μC programs the configuration of the circuit GPIO4. For example, the microcontroller μC first activate the input 108 with a signal dis (see FIGS. 2 and 4) of the circuit GPIO4 for applying a null voltage across the external capacitor Cext, and then programs the signal analog4 for coupling with each other the terminals 106 and 103 of the circuit GPIO4.

At the instant t1, the microcontroller μC activates (step 302) the circuit CTRL, for example by using the bit EN, for example by programming the bit EN at a state which activates the circuit CTRL. Then, circuit PM switches the system 5 in low power mode.

Further, at the instant t1, once circuit CTRL is activated, the circuit CTRL enables in return the circuits COMP, 130 and 140 (step 500). It results that circuit 130 provides voltage VPOL to input 106 of circuit GPIO4, and thus to electrode 104 of capacitor Cext. Voltage on electrode 104 rises until reaching VPOL. In the same time, as the circuits GPIO1, GPIO2 and GPIO3 are not yet controlled by the circuit CTRL, their outputs 103 are in a high impedance state, and voltages on node 101, 111 and 121 rise until reaching VPOL.

In the example of FIG. 10, phase 500 of enabling the circuits 130, 140 and COMP has the duration Init.

At a following instant t2, corresponding to the end of the step 500, the circuit CTRL select a first oscillator LCA, LCB, or LCT, in this example the oscillator LCA. This is done, for example, using the signal analog123 so that the state of the signal analog123 results in the terminal 103 of circuit GPIO1 being coupled with terminal 106 of circuit GPIO1. Thus, from instant t2, the comparator COMP receives the voltage available on node 101.

Instant t2 here corresponds to the beginning of a capture phase CAP with the oscillator LCA.

In the example of FIG. 10, each capture phase CAP has a duration TCAP.

Further, in the example of FIG. 10, each capture phase CAP begins by the temporization iCAP, or, in other words, the circuit CTRL excites the LC oscillator corresponding to this capture phase CAP after the duration iCAP has elapsed.

At a following instant t3 separated from the instant t2 by the duration iCAP, the circuit CTRL controls the application of an excitation signal to oscillator LCA (step 306). In the example of FIG. 10, the excitation signal is a pulse at the ground potential. In the example of FIG. 10, the excitation signal has the duration TP.

At a following instant t4 separated from the instant t3 by the duration TP, voltage across oscillator LCA starts oscillating. From instant t4 until the end of the capture phase CAP, at a following instant t4, the circuit CTRL counts the number CNT of oscillations in the oscillator LCA which exceeds the threshold VTH (step 312).

At the instant t5, the capture phase CAP with the oscillator LCA ends and the capture phase CAP with another of the oscillator LCA, LCB and LCT, in this example the oscillator LCB, begins. For example, at the instant t5, the circuit CTRL deselects oscillator LCA and selects oscillator LCB.

After the duration iCAP has elapsed, at a following instant t6, the circuit CTRL excites the oscillator LCB (step 314). As for the oscillator LCA, in the example of FIG. 10, the excitation signal is a pulse at the ground potential, which has the duration TP.

At a following instant t7 separated from the instant t6 by the duration TP, voltage across oscillator LCB starts oscillating. From instant t7 until the end of the capture phase CAP, at a following instant t8, the circuit CTRL counts the number CNT of oscillations in the oscillator LCB which exceeds the threshold VTH (step 316).

At the instant t8, the circuit CTRL deselects the oscillator LCB.

In the example of FIG. 10, at the instant t8, the circuit CTRL further determines that a tamper detection has to be implemented (step 318, branch Y).

Thus, at the instant t8, the capture phase CAP with the oscillator LCT begins. For example, at the instant t8, the circuit CTRL selects oscillator LCT.

After the duration iCAP has elapsed, at a following instant t9, the circuit CTRL excites the oscillator LCT (step 322). As for the oscillators LCA and LCB, in the example of FIG. 10, the excitation signal is a pulse at the ground potential, which has the duration TP.

At a following instant t10 separated from the instant t9 by the duration TP, voltage across oscillator LCT starts oscillating. From instant t10 until the end of the capture phase CAP, at a following instant t11, the circuit CTRL counts the number CNT of oscillations in the oscillator LCT which exceeds the threshold VTH (step 324).

At the instant t11, the circuit CTRL deselects the oscillator LCT.

At the instant t11, the circuit CTRL further determines, in this example, that circuit CTRL has no need to wake-up the microcontroller μC (step 320, branch N).

Further, in the example of FIG. 10, the measurement phase MEAS comprises a non-null duration TEMPO (step 328, branch Y), and the circuit CTRL is configured to disable circuits 130 and COMP when the duration TEMPO is not null (step 3301). Thus, at the instant t10, the circuit CTRL disables the circuits 130, COMP and 140.

During all the duration TEMPO (step 330), from the instant t10 to a following instant t11, circuits 130, COMP and 140 stay disabled. Thus, voltage on nodes 104, 101, 11 and 121 slowly decreases.

At the end of the duration TEMPO, at the instant t11, the circuit CTRL enables (step 502) the circuits which were turned off at the instant t10.

The circuit CTRL then wait for a duration RECOVERY, which ends at a following instant t12 separated from instant t11 by the duration RECOVERY. The duration RECOVERY, which could have a configurable value, is, for example, determined so that voltage across capacitor Cext reaches the potential Vpol.

Instant t12 corresponds to the end of the current measurement phase MEAS, and to the beginning of the next measurement phase MEAS.

Various embodiments and variants have been described. Those skilled in the art will understand that certain features of these embodiments can be combined and other variants will readily occur to those skilled in the art. In particular, alternatively or complementary to the fact that circuit CTRL is configured to determine whether the microcontroller μC has to switched on (step 320), the system 5 may be configured to periodically wake up the microcontroller PC, for example at a frequency at least two times lower than the frequency of the measurement phases MEAS. For example, when the system 5 is configured to periodically wake up the microcontroller μC steps 320 and 326 may be omitted, and, each time the microcontroller μC is periodically turned on, the microcontroller gets the results of the measurement phases performed by the circuit CTRL while the microcontroller μC was off.

Furthermore, although in system 5 the excitation and the sensing of the LC oscillators, or, in other words, of a network of LC oscillators, is done for determining the position of a rotating wheel, and, optionally, to detect a tamper, a system similar to system 5 may be used for exciting and sensing a network of LC oscillators for other applications.

Finally, the practical implementation of the embodiments and variants described herein is within the capabilities of those skilled in the art based on the functional description provided hereinabove.

What is claimed is:

1. An electronic system comprising:
a first LC oscillator connected to a first general-purpose input/output (GPIO) circuit;
a second LC oscillator connected to a second GPIO circuit;
a comparator;
a threshold generator coupled to an input of the comparator;
a control circuit configured to control a measurement phase comprising a first capture phase and a second capture phase;
a microcontroller coupled to the control circuit; and
a power management circuit configured to switch-off the microcontroller following activation of the control circuit by the microcontroller,
wherein the control circuit is configured, when implementing the first phase of capture, to:
control an application of an excitation signal to the first oscillator via the first GPIO circuit;
control the first GPIO circuit so that oscillations of the first oscillator are provided to the comparator; and
count, based on an output of the comparator, a first number of oscillations in the first oscillator exceeding a first threshold output by the threshold generator; and
wherein the control circuit is configured, when implementing the second phase of capture, to:
control an application of an excitation signal to the second oscillator via the second GPIO circuit;
control the second GPIO circuit so that oscillations of the second oscillator are provided to the comparator; and
count, based on the output of the comparator, a second number of oscillations in the second oscillator exceeding the first threshold.

2. The electronic system of claim 1, wherein for providing oscillations of the first oscillator to the comparator, the control circuit is configured to control, via a third terminal of the first GPIO circuit, a coupling of first and second terminals of the first GPIO circuit, the first terminal being connected to the first oscillator and the second terminal being coupled to the comparator; and
wherein, for providing oscillations of the second oscillator to the comparator, the control circuit is configured to control, via a third terminal of the second GPIO circuit, a coupling of first and second terminals of the second GPIO circuit, the first terminal being connected to the second oscillator and the second terminal being coupled to the comparator.

3. The electronic system of claim 1, wherein the control circuit is configured to control the application of a pulse signal on a fourth terminal of the first GPIO circuit for controlling the application of the excitation signal to the first oscillator, and to control the application of the pulse signal on a fourth terminal of the second GPIO circuit for controlling the application of the excitation signal to second oscillator.

4. The electronic system of claim 3, further comprising a pulse generator circuit for generating the pulse signal, the control circuit being configured, when activated, to control the pulse generator circuit.

5. The electronic system of claim 1, wherein:
the first oscillator is connected between the first GPIO circuit and a first electrode of a capacitor having a second electrode connected to a node for receiving a reference potential;
the second oscillator is connected between the second GPIO circuit and the first electrode of the capacitor;
the electronic system comprises a supplementary general-purpose input/output circuit connected to the first electrode of the capacitor; and
the threshold generator is configured to provide a bias potential to the first electrode of the capacitor via the supplementary general-purpose input/output circuit.

6. The electronic system of claim 5, wherein the microcontroller is configured, before activating the control circuit, to configure the supplementary general-purpose input/output circuit for coupling with each other first and second terminals of supplementary circuit, the first terminal being connected to the first electrode of the capacitor and the second terminal being configured to receive the bias potential.

7. The electronic system of claim 1, wherein, at an end of the last capture phase of each measurement phase, the control circuit is configured to determine whether a temporization duration is to elapse before controlling a beginning of the next measurement phase.

8. The electronic system of claim 7, wherein, when the temporization duration is not null, the control circuit is configured to disable the threshold generator during temporization duration.

9. The electronic system of claim 7, wherein, when the temporization duration is not null, the control circuit is configured to disable the comparator during temporization duration.

10. The electronic system of claim 1, wherein the electronic system comprises a single integrated circuit chip comprising the comparator, the threshold generator, the control circuit, the microcontroller and the power management circuit, the first and second oscillators are external relative to the single integrated circuit chip.

11. The electronic system of claim 1, wherein the electronic system comprises a first voltage domain comprising the control circuit and a second voltage domain comprising the microcontroller, the power management circuit being configured to switch-off the second voltage domain following the activation of the control circuit by the microcontroller.

12. The electronic system of claim 1, wherein, at each measurement phase, the control circuit is configured to compare the first number and the second number with a second threshold to determine a position of a rotating wheel.

13. The electronic system of claim 12, wherein the control circuit is configured to send a wake-up event to the power management circuit when a number of revolution of the wheel reaches a target value, the number of revolution being determined by the control circuit based on the position of the rotating wheel determined at each measurement phase of a plurality of measurement phases, and the power management circuit being configured to switch-on the microcontroller when receiving the wake-up event.

14. The electronic system of claim 1, wherein, at each measurement phase, the control circuit is configured to compare the first number and the second number with a low boundary value and a high boundary value.

15. The electronic system of claim 14, wherein the control circuit is configured to send a wake-up event to the power management circuit when at least one of the first and second number is outside a range of values from the low boundary value to the high boundary value, and the power management circuit being configured to switch-on the microcontroller when receiving the wake-up event.

16. The electronic system of claim 1, further comprising a third LC oscillator connected to a sixth GPIO circuit, wherein at least one measurement phase controlled by the control circuit comprises a third capture phase further to the first and the second capture phases, and wherein the control circuit is configured, when implementing the third phase of capture, to:
control an application of an excitation signal to the third oscillator via the sixth GPIO circuit;
control the sixth GPIO circuit so that oscillations of the third oscillator are provided to the comparator;
count, based on the output of the comparator, a third number of oscillations in the third oscillator exceeding the first threshold; and
detect a tamper by comparing the third number with a third threshold and, preferably, to send a wake-up event to the power management circuit and an interruption signal to the microcontroller when a tamper is detected.

17. A method implemented in an electronic system, the method comprising:
activating a control circuit with a microcontroller;
switching-off the microcontroller following the activation of the control circuit by the microcontroller; and
using the activated control circuit to implement a measurement phase comprising a first capture phase with a first LC oscillator connected to a first general-purpose input/output circuit and a second capture phase with a second LC oscillator connected to a second general-purpose input/output circuit,
wherein the first capture phase comprises:
controlling an application of an excitation signal to the first oscillator via the first GPIO circuit;
controlling the first GPIO circuit so that oscillations of the first oscillator are compared to a threshold voltage; and
counting a first number of oscillations in the first oscillator exceeding the threshold voltage; and
wherein the second capture phase comprises:
controlling an application of an excitation signal to the second oscillator via the second GPIO circuit;
controlling the second GPIO circuit so that oscillations of the second oscillator are compared to the threshold voltage; and
counting a second number of oscillations in the second oscillator exceeding the threshold voltage.

18. The method of claim 17, further comprising, at an end of the last capture phase of each measurement phase, determining whether a temporization duration is to elapse before controlling a beginning of the next measurement phase.

19. The method of claim 17, further comprising, at each measurement phase, comparing the first number and the second number with a second threshold to determine a position of a rotating wheel.

20. The method of claim 17, further comprising, at each measurement phase, comparing the first number and the second number with a low boundary value and a high boundary value.
